(19) United States
(12) Patent Application Publication
(10) Pub. No.: US 2026/0113842 A1
(43) Pub. Date: Apr. 23, 2026

(54) PRINTED CIRCUIT BOARD

(71) Applicant: SAMSUNG ELECTRO-MECHANICS CO., LTD., Suwon-si (KR)

(72) Inventors: Sang Hyuk Son, Suwon-si (KR); Young June Jun, Suwon-si (KR)

(73) Assignee: SAMSUNG ELECTRO-MECHANICS CO., LTD., Suwon-si (KR)

(21) Appl. No.: 19/248,242

(22) Filed: Jun. 24, 2025

(30) Foreign Application Priority Data
Oct. 18, 2024 (KR) 10-2024-0142935

(51) Int. Cl. H05K 1/11; H05K 3/40

(52) U.S. Cl. CPC H05K 1/112; H05K 3/4038; H05K 2201/09372

(57) ABSTRACT

A printed circuit board includes a first insulating layer having first and second surfaces opposing each other in a thickness direction, and a second insulating layer disposed on one side of the first surface. A conductive via extends through the first insulating layer between the first and second surfaces. An inner conductor layer is disposed between an inner wall of the through-hole and the conductive via. A first pad is disposed on the first surface of the first insulating layer, farther from the insulating layer than the second insulating layer, and includes a first conductor layer and a second conductor layer on the first conductor layer. A second pad is disposed on the second surface of the first insulating layer and includes a third conductor layer and a fourth conductor layer. The inner conductor layer forms an interface with, and is in contact with, the first conductor layer.

### CROSS-REFERENCE TO RELATED APPLICATIONS

This application claims the benefit of priority to Korean Patent Application No. 10-2024-0142935 filed on Oct. 18, 2024 in the Korean Intellectual Property Office, the disclosures of which are incorporated herein by reference in its entirety.

### BACKGROUND

### 1. FIELD

The present disclosure relates to a printed circuit board.

### 2. DESCRIPTION OF RELATED ART

In order to respond to the recent trend for lighter and smaller mobile devices, the need to implement lighter and thinner printed circuit boards mounted thereon is also gradually increasing. Meanwhile, as mobile devices have become lighter and thinner, an undercut phenomenon may occur during the process of implementing fine circuits, which can cause fine circuit defects. In response to this technical demand, research is continuously performed to implement a circuit having a fine line width and spacings with improving reliability.

### SUMMARY

An example embodiment of the present disclosure is to provide a printed circuit board on which a circuit having a fine line width and spacings may be implemented.

According to an example embodiment, a printed circuit board includes a first insulating layer having first and second surfaces opposing each other in a thickness direction; a second insulating layer disposed on a side of the first surface of the first insulating layer; a conductive via disposed in a through-hole formed in the thickness direction in the first insulating layer; an inner conductor layer disposed between an inner wall of the through-hole and the conductive via; and a first pad disposed on the side of the first surface of the first insulating layer further from the first insulating layer than the second insulating layer and including a first conductor layer and a second conductor layer disposed on the first conductor layer, wherein the inner conductor layer forms an interface with the first conductor layer and is in contact with the first conductor layer.

An upper surface of the inner conductor layer may be in contact with a lower surface of the first conductor layer.

An upper surface of the inner conductor layer and an upper surface of the second insulating layer may form a coplanar surface.

The inner conductor layer may not cover an upper surface of the second insulating layer.

The inner conductor layer may not be in contact with the second conductor layer.

The inner conductor layer includes first and second inner conductor layers, wherein the first inner conductor layer may be disposed closer to an inner wall of the through-hole than the second inner conductor layer.

Upper surfaces of the first and second inner conductor layers may be in contact with a lower surface of the first conductor layer.

Upper surfaces of the first and second inner conductor layers and an upper surface of the second insulating layer may form a coplanar surface.

The first and second inner conductor layers may not cover an upper surface of the second insulating layer.

The first and second inner conductor layers may not be in contact with the second conductor layer.

The conductive via may have a form protruding further outwardly of the first insulating layer from the first surface than the inner conductor layer.

A region of the second conductor layer corresponding to the conductive via may have a protruding shape.

The conductive via may protrude outwardly from the first surface of the first insulating layer.

A thickness of the first conductor layer may be 0.5 μm or more and 2 μm or less.

A distance protruding laterally from the through-hole of the first insulating layer in the first pad may be 25 μm or less.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is an enlarged view of a portion of FIG. 3;

FIG. 5 is a cross-sectional view schematically illustrating another example of a printed circuit board;

FIG. 6 is a cross-sectional view schematically illustrating another example of a printed circuit board; and

FIGS. 7 to 15 illustrate a method for manufacturing a printed circuit board.

### DETAILED DESCRIPTION

Hereinafter, embodiments of the present disclosure will be described as follows with reference to the attached drawings. The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Accordingly, shapes and sizes of elements in the drawings may be exaggerated for clear description, and elements indicated by the same reference numerals are the same elements in the drawings.

### Electronic Device

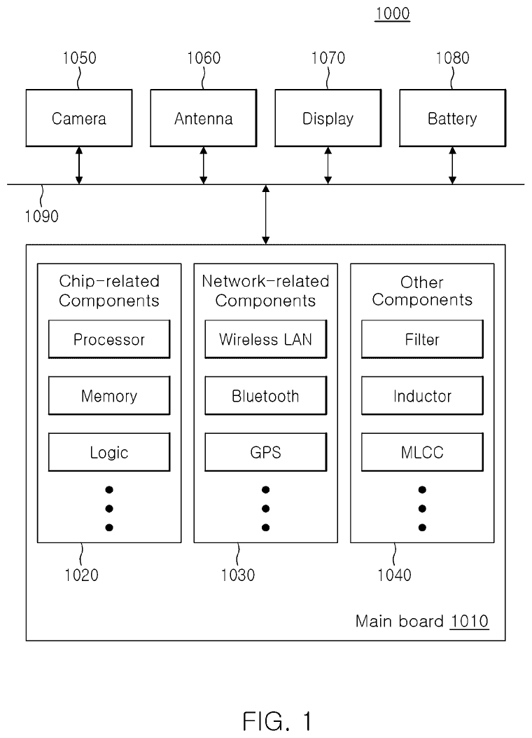

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disc (CD) drive, a digital versatile disk (DVD) drive, or the like. The other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

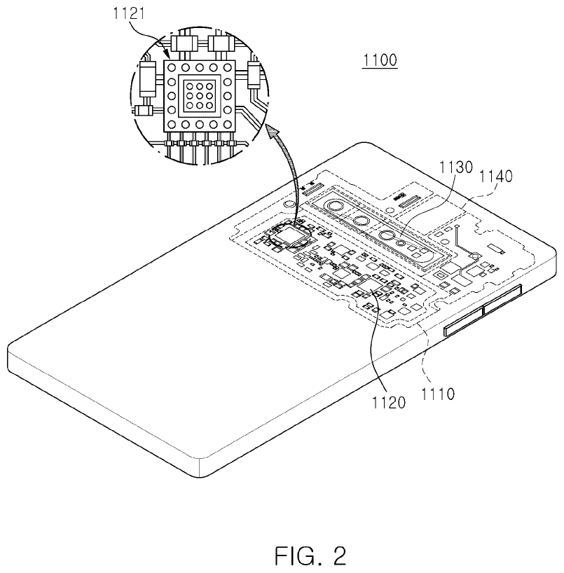

FIG. 2 is a perspective view schematically illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Cricuit Board

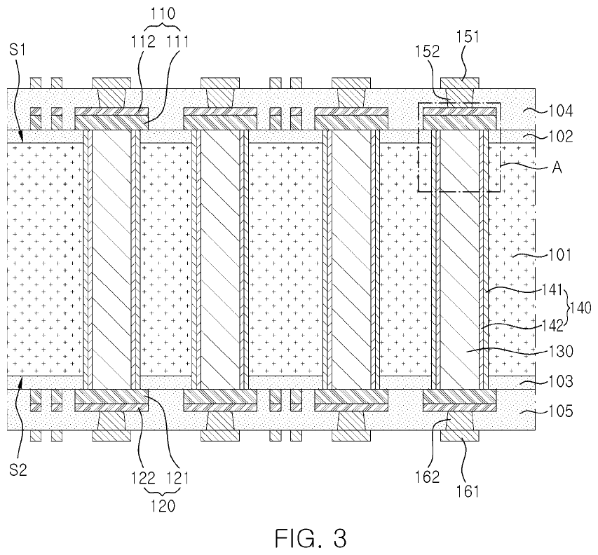

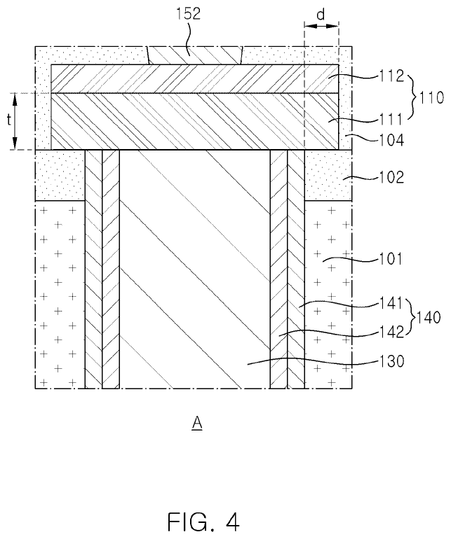

FIG. 3 is a cross-sectional view schematically illustrating an example of a printed circuit board, and FIG. 4 is an enlarged view of a portion of FIG. 3. Referring to FIGS. 3 and 4, a printed circuit board 100 according to the present embodiment includes a first insulating layer 101, a second insulating layer 102, a conductive via 130, an inner conductor layer 131, and a first pad 110 including a first conductor layer 111 and a second conductor layer 112. Here, the inner conductor layer 131 disposed in a through-hole of the first insulating layer 101 forms an interface with the first conductor layer 111 and is in contact with the first conductor layer. In other words, the inner conductor layer 131 forms an interface with the first conductor layer 111 as a separate structure rather than as an integral structure. Through the structure, the conductive via 130, the first pad 110, or the like, may be made finer and a pitch thereof may be effectively reduced.

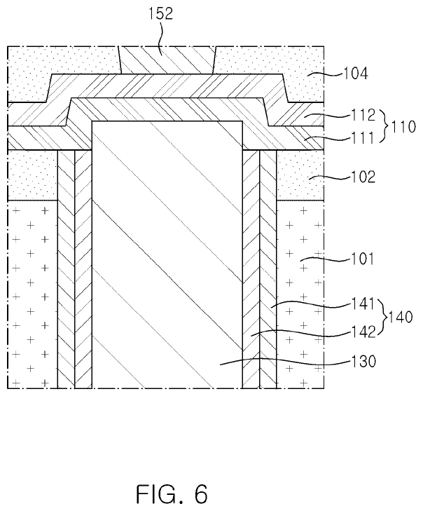

The first insulating layer 101 may be a core insulating layer. The first insulating layer 101 may include an insulating material such as an insulating resin, such as a thermosetting resin such as an epoxy resin or a thermoplastic resin such as a polyimide, or a material in which the resins are mixed with an inorganic filler such as silica, or a resin impregnated into a core material such as glass fiber, glass cloth, glass fabric, or the like, together with an inorganic filler, for example, copper clad laminate (CCL), but an example embodiment thereof is not limited thereto. The first insulating layer 101 has a first surface S1 and a second surface S2 opposing each other in a thickness direction (vertical direction based on the illustrated form). In addition, a through-hole (H in FIG. 6) is formed in the thickness direction in the first insulating layer 101. The first insulating layer 101 may be thicker than the insulating layers 102 and 103 respectively disposed on the sides of the first surface S1 and the second surface S2. In this case, the thicknesses of respective layers may be measured using a scanning microscope or an optical microscope based on a polished or cut cross-section of the printed circuit board in a vertical direction. When the thickness is not constant, the thickness relationship may be compared by using an average value of the thickness of each object measured at five arbitrary points.

A second insulating layer 102 may be disposed on the side of the first surface S1 of the first insulating layer 101, and a third insulating layer 103 may be disposed on the side of the second surface S2 of the first insulating layer 101. As an example of an insulating material that can be included in the second and third insulating layers 102 and 103, an insulating resin such as a thermosetting resin such as an epoxy resin or a thermoplastic resin such as a polyimide, or a material in which the resins are mixed with an inorganic filler such as silica, or a resin impregnated into a core material such as glass fiber, glass cloth, glass fabric, or the like, together with an inorganic filler, for example, Ajinomoto build-up film (ABF), prepreg, or the like may be used, but an example embodiment thereof is not limited thereto. In addition, as additional insulating layers, a fourth insulating layer 104 and a fifth insulating layer 105 may be disposed on the side of the first surface S1 and the side of the second surface S2 of the first insulating layer 101, respectively, and the fourth insulating layer 104 and the fifth insulating layer 105 may be build-up insulating layers.

A conductive via 130 may be disposed in a through-hole formed in the thickness direction in the first insulating layer 101, and a first pad 110 and a second pad 120 may be connected to each other by the conductive via 130. In addition, an inner conductor layer 140 may be disposed between an inner wall of the through-hole of the first insulating layer 101 and the conductive via 130. In this case, the inner conductor layer 140 may include a plurality of conductor layers, for example, a first inner conductor layer 141 and a second inner conductor layer 142. Here, the first inner conductor layer 141 may be disposed closer to the inner wall of the through-hole of the first insulating layer 101 than the second inner conductor layer 142.

The conductive via 130 may include a metal material such as copper (Cu), aluminum (Al), silver (Ag), tin (Sn), gold (Au), nickel (Ni), lead (Pb), titanium (Ti), or an alloy thereof, and may perform various functions depending on the design of a corresponding layer. For example, the conductive via 130 may include a ground via, a power via, a signal via, or the like. In an example, a conductive via 130 may be formed by filling a plug into the through-hole after the inner conductor layer 140 is formed by plating. The conductive via 130 may have a roughly circular or elliptical shape based on a planar shape viewed from above. In addition, in terms of securing adhesion by increasing a specific surface area, the conductive via 130 may have a polygonal shape on a plane, as well as a so-called flower shape in which multiple circles or ovals are overlapped.

A first pad 110 is disposed on the side of the first surface S1 of the first insulating layer 101 farther from the first insulating layer 101 than the second insulating layer 102, and includes a first conductor layer 111 and a second conductor layer 112. In addition, a second pad 120 may be disposed on the side of the second surface S2 of the first insulating layer 101, and the second pad 120 may include a third conductor layer 121 and a fourth conductor layer 122. The second pad 120 may be implemented in the same form as the first pad 110, and hereinafter, the structure of the first pad 110 and the conductive via 130 on the side of the first surface S1 of the first insulating layer 101 will be described, but this description may also be applied to the second pad 120 and the conductive via 130 disposed on the side of the second surface S2 of the first insulating layer 101.

In the present embodiment, the inner conductor layer 140 forms an interface with the first conductor layer 111 and is in contact with the first conductor layer 111. As a more specific example, an upper surface of the inner conductor layer 140 may be in contact with a lower surface of the first conductor layer 111. In addition, as shown in the illustrated form, the upper surface of the inner conductor layer 140 and the upper surface of the second insulating layer 102 may form a coplanar surface. Such a coplanar structure may be obtained by performing a process, such as polishing a portion of the inner conductor layer 140 disposed above the second insulating layer 102, to be described later. As a more specific form, the inner conductor layer 140 may not cover the upper surface of the second insulating layer 102. In addition, the inner conductor layer 140 may not be in contact with the second conductor layer 112.

When the inner conductor layer 140 includes first and second inner conductor layers 141 and 142, the upper surfaces of the first and second inner conductor layers 141 and 142 may be in contact with the lower surface of the first conductor layer 111. The upper surfaces of the first and second inner conductor layers 141 and 142 and the upper surface of the second insulating layer 102 may be coplanar. The first and second inner conductor layers 141 and 142 may not cover the upper surface of the second insulating layer 102. The first and second inner conductor layers 141 and 142 may not be in contact with the second conductor layer 112.

As described above, in the present embodiment, the inner conductor layer 140 may be formed through a separate process, for example, a separate plating process, rather than being formed integrally with the first conductor layer 111, so that the inner conductor layer 140 and the first conductor layer 111 may form an interface and be in contact with each other. When the inner conductor layer 140 and the first conductor layer 111 are plated at once and implemented integrally, it may be difficult to implement a fine circuit in a subsequent etching process. In this embodiment, after etching a region of the inner conductor layer 140 formed on the second insulating layer 102, a relatively thin first conductor layer 111 may be formed, and thus the first pad 110 may be made finer. In other words, the inner conductor layer 140 may be formed separately from the first conductor layer 111, so that the first pad 110 may be formed to have a thin and narrow width even after etching, and accordingly, a greater number of conductive vias 130 may be disposed in a space of the same size. Specifically, a thickness (t) of the first conductor layer 111 may be 0.5 μm or more and 2 μm or less, and further, a distance (d) protruding laterally from the through-hole of the first insulating layer 101 in the first pad 110 may be reduced to a level of 25 μm or less. Accordingly, the size of the first pad 110 may be reduced, and the alignment with the conductive via 130 may be improved. Furthermore, a spacing between conductive vias 130 may also be made finer, and for example, the spacing between adjacent conductive vias 130 may be implemented at a level of 300 μm or less.

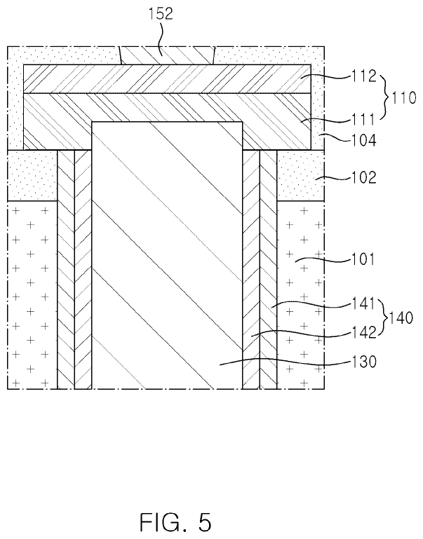

Meanwhile, as in the modified example of FIG. 5, the conductive via 130 may have a form protruding farther outward from the first insulating layer 101 at the first surface S1 than the inner conductor layer 140. In this case, as in the modified example of FIG. 6, the second conductor layer 112 may have a shape in which a region corresponding to the conductive via 130 protrudes. In addition, the conductive via 130 may take a form protruding outwardly from the first surface S1 of the first insulating layer 101. When the conductive via 130 has a protruding structure as in the modified examples, the electrical and physical contact with the first pad 110 may be improved.

Meanwhile, when describing additional components of the printed circuit board 100, conductor patterns 151 and 161 may be disposed on a first pad 110 and a second pad 120, respectively, and in addition thereto, a conductor pattern may be disposed at the same level as the first pad 110 and the second pad 120. In this case, vias 152 and 162 respectively connecting the first and second pads 110 and 120 and the conductor patterns 151 and 161 may be provided.

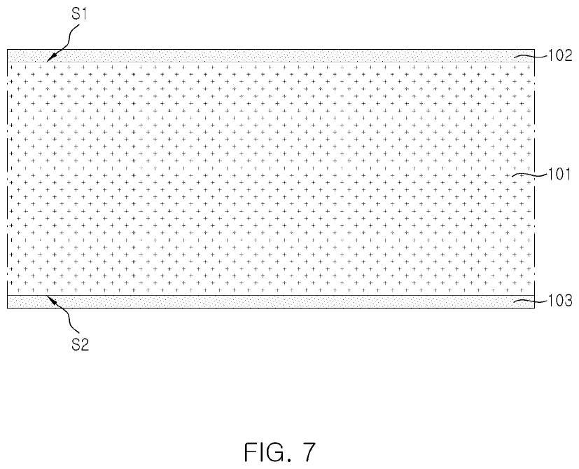

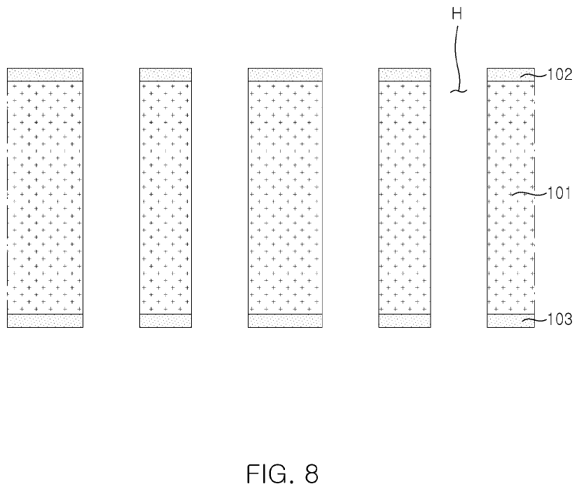

Hereinafter, an example of a method for manufacturing a printed circuit board will be described with reference to FIGS. 7 to 15. First, referring to FIGS. 5 and 6, a first insulating layer 101 is provided and a through-hole H penetrating through the first insulating layer 101 in a thickness direction is formed, and here, a second insulating layer 102 and a third insulating layer 103 are disposed on the first surface S1 and the second surface S2 of the first insulating layer 101, respectively. As an example, a method of stacking ABF on both surfaces of the first insulating layer 101 remaining after removing copper foil from both surfaces of a Copper Clad Laminate (CCL) may be used to form a second insulating layer 102 and a third insulating layer 103. The through-hole H of the first insulating layer 101 may be formed by an appropriate processing method, for example, laser processing, and then subjected to a desmear process.

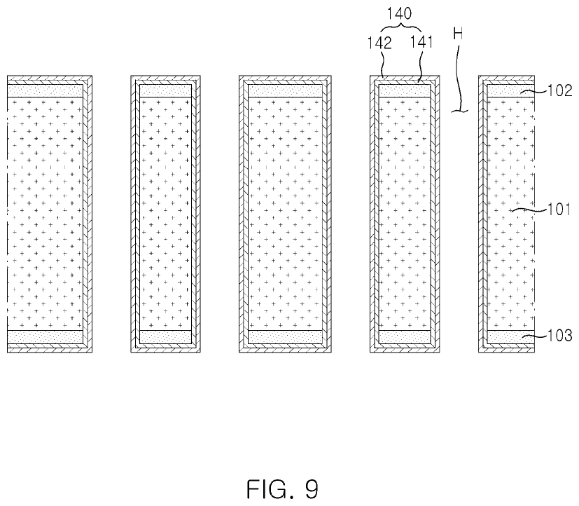

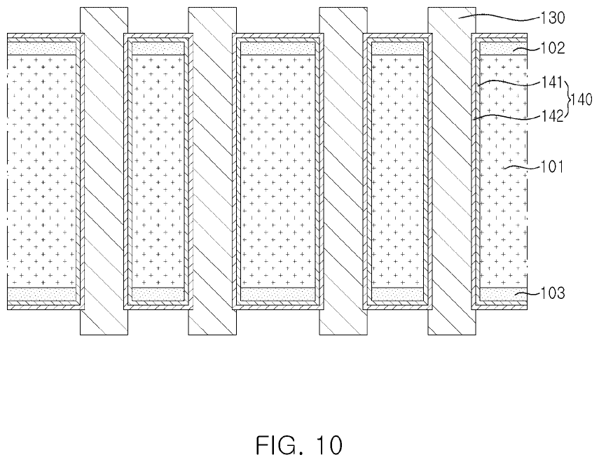

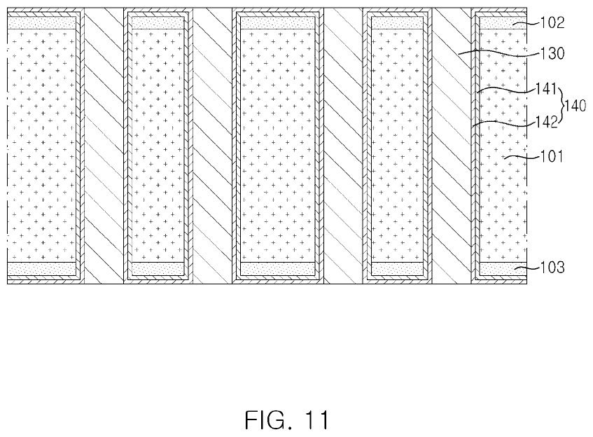

Next, as shown in FIG. 9, an inner conductor layer 140 may be formed in the through-hole H of the first insulating layer 101, and the inner conductor layer 140 may be formed on a side of the first surface S1 and a side of the second surface S2 of the first insulating layer 101 in addition to the through-hole H. The inner conductor layer 140 may include a first inner conductor layer 141 and a second inner conductor layer 142, and in this case, the first inner conductor layer 141 may be formed by electroless plating, and the second inner conductor layer 142 may be formed by electrolytic plating. Subsequently, referring to FIG. 10, a conductive via 130 may be formed by using a process such as filling a plug into the through-hole H of the first insulating layer 101, and in addition thereto, a plating process that can be used in the relevant technical field may be used. Thereafter, if necessary, a region of the conductive via 130 protruding outwardly as illustrated in FIG. 11 may be removed through a polishing process.

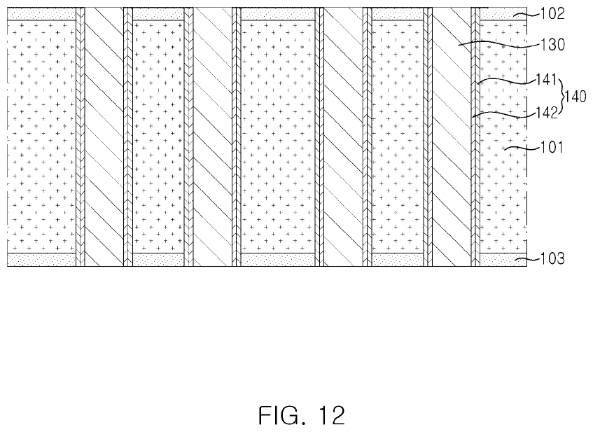

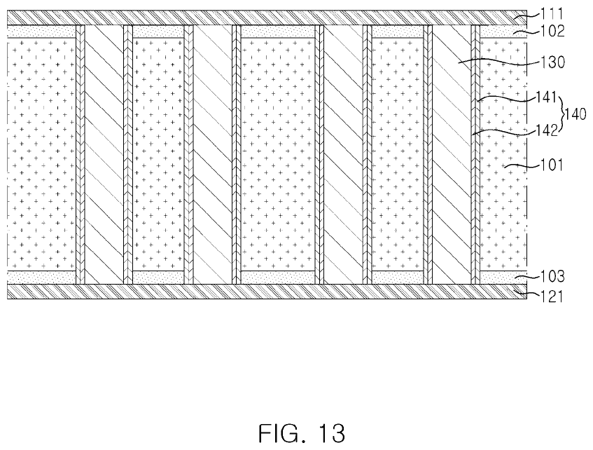

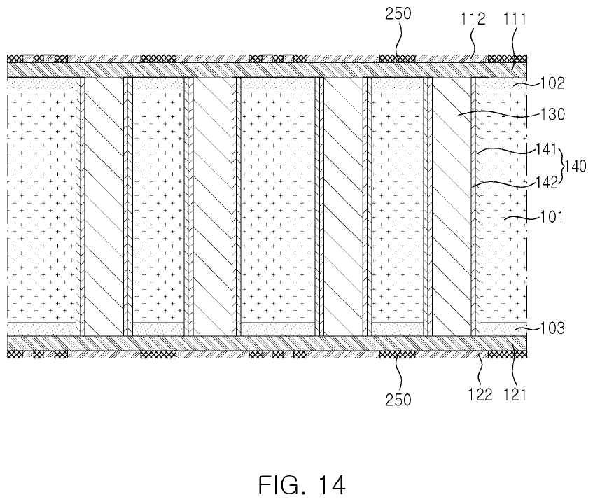

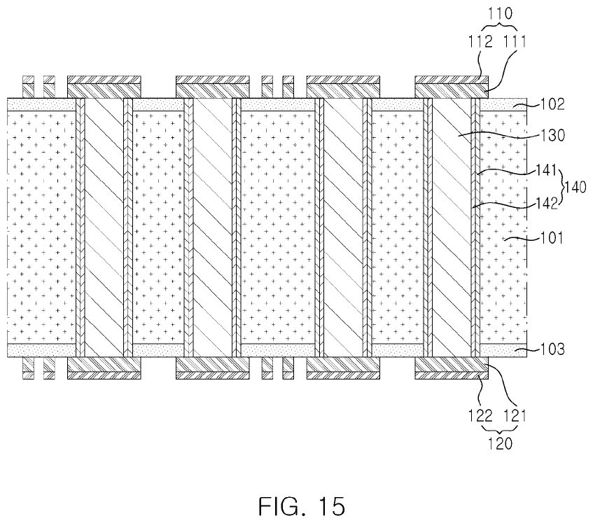

Next, as shown in FIG. 12, at least a portion of a region of the inner conductor layer 140 covering the first surface S1 and the second surface S2 of the first insulating layer 201 is removed. In the process, the upper surface of the second insulating layer 102 and the upper surface of the inner conductor layer 140 may form a coplanar surface. In addition, the conductive via 130 may be additionally polished to remove a region protruding in a vertical direction. Alternatively, the region protruding in a vertical direction from the conductive via 130 may be left as is, and in this case, the structure of FIG. 5 may be obtained. Referring to FIGS. 13 and 14, first and second conductor layers 111 and 112 and third and fourth conductor layers 121 and 122 are formed thereafter. Here, as an example of the process, the second conductor layer 112 and the fourth conductor layer 122 may be formed by forming a mask layer 250 and then performing pattern plating on an open region. Thereafter, as illustrated in the form of FIG. 15, the mask layer 250 may be removed, and portions of the conductor layers 111, 112, 121, and 122 may be removed through an etching process to obtain the first pad 110 and the second pad 120 having the structure described above. Thereafter, a printed circuit board of the form described above may be obtained through an appropriate build-up process.

In the present disclosure, the meaning on a cross-section may refer to a cross-sectional shape when an object is cut vertically, or a cross-sectional shape when the object is viewed from the side. Furthermore, the meaning on a plane may refer to a planar shape when the object is horizontally cut, or a planar shape when the object is viewed from the top or the bottom.

In the present disclosure, for convenience, an upper side, an upper portion, and an upper surface are used to refer to a downward direction with respect to a cross-section of a drawing, and a lower side, a lower portion, and a lower surface are used to refer to an opposite direction thereof. However, this is a definition of direction for the convenience of explanation, and the scope of the claim is not specifically limited by the description of this direction, and the concept of upper/lower may be changed at any time.

In the present disclosure, a term connected is a concept including not only directly connected but also indirectly connected through an adhesive layer or the like. Furthermore, a term electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, a printed circuit board according to an example embodiment of the present disclosure may be provided with a circuit having a fine line width and spacings.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first insulating layer having first and second surfaces opposing each other in a thickness direction;
a second insulating layer disposed on a side of the first surface of the first insulating layer;
a conductive via disposed in a through-hole formed in the thickness direction in the first insulating layer;
an inner conductor layer disposed between an inner wall of the through-hole and the conductive via; and
a first pad disposed on the side of the first surface of the first insulating layer farther from the first insulating layer than the second insulating layer and including a first conductor layer and a second conductor layer disposed on the first conductor layer,
wherein the inner conductor layer forms an interface with the first conductor layer and is in contact with the first conductor layer.

2. The printed circuit board of claim 1, wherein an upper surface of the inner conductor layer is in contact with a lower surface of the first conductor layer.

3. The printed circuit board of claim 2, wherein the upper surface of the inner conductor layer and an upper surface of the second insulating layer are coplanar.

4. The printed circuit board of claim 2, wherein the inner conductor layer does not cover the upper surface of the second insulating layer.

5. The printed circuit board of claim 1, wherein the inner conductor layer is not in contact with the second conductor layer.

6. The printed circuit board of claim 1, wherein the inner conductor layer includes first and second inner conductor layers, wherein the first inner conductor layer is disposed closer to the inner wall of the through-hole than the second inner conductor layer.

7. The printed circuit board of claim 6, wherein the upper surfaces of the first and second inner conductor layers are in contact with the lower surface of the first conductor layer.

8. The printed circuit board of claim 7, wherein the upper surfaces of the first and second inner conductor layers and the upper surface of the second insulating layer are coplanar.

9. The printed circuit board of claim 7, wherein the first and second inner conductor layers do not cover the upper surface of the second insulating layer.

10. The printed circuit board of claim 7, wherein the first and second inner conductor layers are not in contact with the second conductor layer.

11. The printed circuit board of claim 1, wherein the conductive via protrudes farther outward from the first surface of the first insulating layer than the inner conductor layer.

12. The printed circuit board of claim 11, wherein a region of the second conductor layer corresponding to the conductive via has a protruding shape.

13. The printed circuit board of claim 12, wherein the conductive via protrudes outward from the first surface of the first insulating layer.

14. The printed circuit board of claim 1, wherein the first conductor layer has a thickness of 0.5 μm or more and 2 μm or less.

15. The printed circuit board of claim 1, wherein a lateral protrusion distance of the first pad from the through-hole of the first insulating layer is 25 μm or less.

16. A printed circuit board, comprising:
a first insulating layer having first and second surfaces opposing each other in a thickness direction;
a second insulating layer disposed on one side of the first surface of the first insulating layer;
a conductive via disposed in a through-hole formed in the thickness direction of the first insulating layer;
an inner conductor layer disposed between an inner wall of the through-hole and the conductive via;
a first pad disposed on the side of the first surface of the first insulating layer, farther from the first insulating layer than the second insulating layer, the first pad including a first conductor layer and a second conductor layer disposed on the first conductor layer; and
a second pad disposed on a side of the second surface of the first insulating layer, the second pad including a third conductor layer and a fourth conductor layer; wherein the inner conductor layer forms an interface with the first conductor layer and is in contact with the first conductor layer.

17. The printed circuit board of claim 16, wherein the conductive via has a protruding structure extending beyond the first surface of the first insulating layer and the second surface of the first insulating layer in the thickness direction.
